(19) United States
(12) Patent Application Publication
(10) Pub. No.: US 2008/0178934 A1
(43) Pub. Date: Jul. 31, 2008

(54) SOLAR CELL SYSTEMS FOR USE IN BUILDINGS

(75) Inventor: Vladimir Odnoblyudov, La Jolla, CA (US)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: YBR Solar, Inc., La Jolla, CA (US)

(21) Appl. No.: 11/956,950

(22) Filed: Dec. 14, 2007

Related U.S. Application Data
(60) Provisional application No. 60/869,984, filed on Dec. 14, 2006.

(51) Int. Cl. H01L 31/02; B05D 5/12

(52) U.S. Cl. 136/262; 427/74

(57) ABSTRACT

Methods are disclosed of fabricating a solar cell system. A solar cell is formed over a substrate. The substrate is attached to a carrier. A translucent or transparent protective cover is overlaid over the solar cell to produce the solar cell system, which is deployed onto an exterior of a building.

### CROSS REFERENCE TO RELATED APPLICATION

This application is a nonprovisional of and claims the benefit of U.S. Provisional Application No. 60/869,984, entitled “SOLAR CELL SYSTEMS FOR USE IN BUILDINGS,” filed Dec. 14, 2006, the entire disclosure of which is incorporated herein by reference for all purposes.

### BACKGROUND OF THE INVENTION

This application relates generally to solar cell systems. More specifically, this application relates to the use of solar cell systems in residential and office buildings.

While there have long been concerns about the development of energy sources, some of these concerns have become particularly acute is the last several years. These concerns are largely twofold: there is a concern that the use of certain energy sources, particularly those that are carbon-based, have undesirable environmental impacts. These energy sources are also largely nonrenewable, presenting concerns about the systematic depletion of them. Many alternatives have been proposed for producing energy that are drawn from sources that have low environmental impacts and are renewable, but many of these proposals suffer from a variety of inefficiencies related to the generation techniques.

In addition, many of these proposals suffer from the fact that they require substantial modifications to existing infrastructures. While the energy generation from the techniques themselves may be attractive and generally efficient, the impact on infrastructure makes them uneconomical. In addition, there are numerous regulatory provisions that have the potential to frustrate attempts to deploy new energy-generation technologies. Navigating such a regulatory framework frequently acts to discourage large-scale implementation of many promising forms of technology.

There is accordingly a general need in the art for improved methods and systems of generating energy in environmentally benign ways.

### BRIEF SUMMARY OF THE INVENTION

Embodiments of the invention provide solar systems integrated with buildings, permitting the solar cells to convert light incident onto the buildings into electrical or other types of energy. In some embodiments, light incident on translucent parts of the building, such as onto windows, is converted, while in other embodiments, light incident onto opaque parts of the building is converted.

Methods are thus provided of fabricating a solar cell system. A solar cell is formed over a substrate. The substrate is attached to a carrier. A translucent or transparent protective cover is overlaid over the solar cell to produce the solar cell system, which is deployed onto an exterior of a building.

The substrate may be transparent at visible wavelengths, such as when it comprises GaP. When the carrier is also translucent or transparent, the solar cell system may be deployed onto the exterior of the building as part of a window in the building. In other instances, the substrate is opaque at visible wavelengths. The carrier may then comprise a construction panel, with the solar cell being deployed onto the exterior of the building as part of an opaque portion of the exterior of the building.

### BRIEF DESCRIPTION OF THE DRAWINGS

A further understanding of the nature and advantages of the present invention may be realized by reference to the remaining portions of the specification and the drawings wherein like reference numerals are used throughout the several drawings to refer to similar components. In some instances, a sublabel is associated with a reference numeral and follows a hyphen to denote one of multiple similar components. When reference is made to a reference numeral without specification to an existing sublabel, it is intended to refer to all such multiple similar components.

FIG. 1 is a schematic illustration of the structure of a typical office building that highlights portions having different desired optical characteristics;

FIG. 2 is a flow diagram summarizing methods of fabricating a solar cell system as part of a translucent structure integrated with a building;

FIGS. 3A and 3B are schematic illustrations of the structure of the solar cell system used in FIG. 2;

FIG. 4 is a flow diagram summarizing methods of fabricating a solar cell system as part of an opaque structure integrated with a building; and

FIGS. 5A and 5B are schematic illustrations of the structure of the solar cell system used in FIG. 4.

### DETAILED DESCRIPTION OF THE INVENTION

Embodiments of the invention provide a structure for a solar device that may be readily incorporated into existing construction technologies with only minimal impact on existing infrastructures, and largely accommodating existing regulatory provisions. These embodiments implement a solar cell as part of the construction of a building and make use of materials that may be readily integrated with existing construction techniques. As such, these embodiments provide minimal impact on construction techniques currently used for buildings and on the lifestyle of those who live and/or work in such buildings.

Different buildings have different structures that are intended to accommodate the particular uses of the buildings. For example, many office buildings tend to have a relatively large number of windows, reflecting the fact that the interior volume of the building is large and that privacy concerns are different from residential buildings. By contrast, residential buildings tend to have fewer windows, although the diversity of structures used both residentially and commercially are such that there are numerous exceptions to these broad generalizations.

What is common about buildings is that they almost always have portions that have different optical requirements. Part of a typical building is opaque, usually forming the basic structure of the building. Within this structure are transparent or translucent portions that act as windows to allow natural light to propagate to the interior of the structure. As used herein, the term “windows” is intended to refer to any structure incorporated within a building that is intended to allow light of visible wavelengths to propagate to an interior of the building. While this includes conventional windows on the sides of typically rectilinear buildings, it also encompasses a variety of other structures such as skylights that may be formed at other locations of the building and that may accommodate a variety of nonconventional shapes and structures for the building.

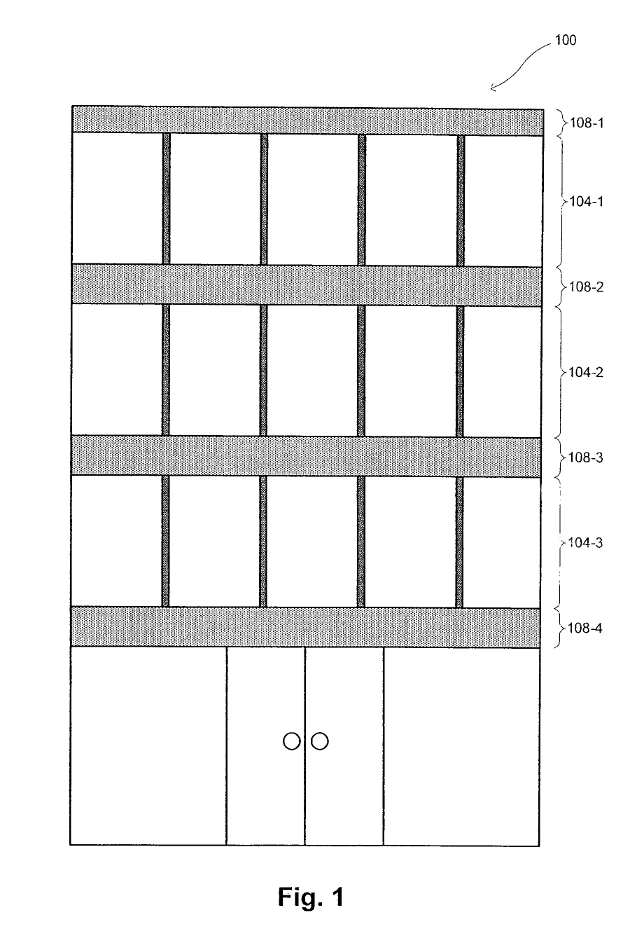

A typical structure for a building is shown schematically in FIG. 1. This is a structure that is often used for office buildings and is presented merely to illustrate the different optical characteristics that exist for different parts of the building. More generally, embodiments of the invention may be used for any shaped building having any distribution of exterior optical characteristics. In FIG. 1, the building 100 has an approximately layered structure above an entrance to the building, the layers of the structure corresponding to floors of what is often referred to as a “high-rise” building. This layered structure provides windows in window layers 104 that allow light to reach offices of workers in the building 100. These window layers are separated by panel layers 108, which correspond to structures used between the high-rise floors. The panel layers 108 often comprise drivet, light-weight stone, brick, or similar materials along the exterior of the building 100.

Embodiments of the invention provide solar cell structures that may be deployed in the different optical areas. This permits energy to be collected from light incident on any portion of a building. In different embodiments, structures that accommodate translucency may be deployed as part of some or all of the window structures, structures that accommodate opaqueness may be deployed as part of some or all of the opaque structures, or a combination of such deployments may be used.

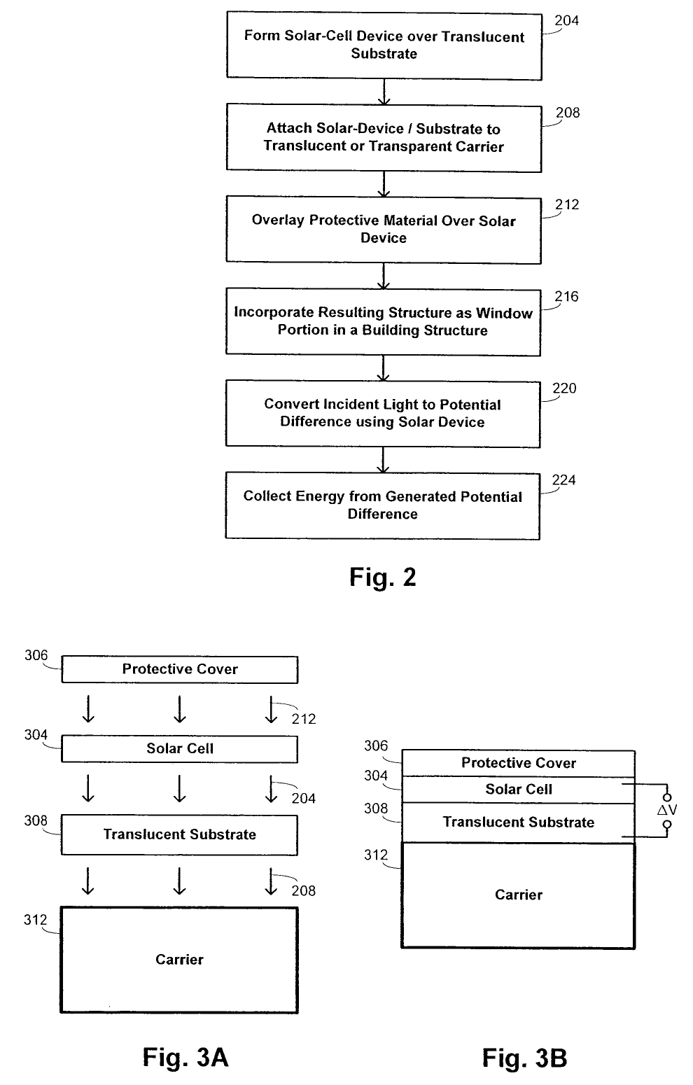

The flow diagram of FIG. 2 summarizes methods for producing solar cell systems suitable for deployment in areas of a building where translucency is desired. Some of the steps in this method are also indicated schematically in FIG. 3A, which shows the different structures used in forming the solar cell systems. FIG. 3B shows a structure for an assembled solar cell system. While a number of steps are indicated specifically the flow diagram, this is merely a detailed illustration of certain exemplary embodiments. In other embodiments, some of the specifically indicated steps might be omitted, additional steps not specifically indicated might be performed, and/or the order of the steps might be varied from what is indicated by the drawing.

As indicated at block 204 in FIG. 2 and by arrows 204 in FIG. 3A, a solar-cell device 304 is formed over a translucent or transparent substrate 308. One suitable substrate comprises GaP, which is a widely commercially available III-V compound semiconductor substrate that is substantially translucent. In some embodiments, undoped GaP is used, although other embodiments are able to accommodate some level of dopants that does not interfere excessively with the general translucency of the substrate. The bandgap of undoped GaP is 2.27 eV, which allows the crystal to transmit a portion of the electromagnetic spectrum having wavelengths longer than yellow wavelengths. The formation of the solar-cell device at block 204 may be performed in a number of different ways, one example being the use of an epitaxial-growth process that uses chemical-vapor deposition or other growth techniques. In alternative embodiments, a previously formed substantially transparent or translucent solar-cell device 304 may be bonded or otherwise attached to the substrate 308. In this case, substrate 308 may comprise any substantially transparent or translucent substrate and does not need to comprise a semiconductor. For example, substrate 308 may comprise glass or plastic.

At block 208, the combined solar-device/substrate is attached to a translucent or transparent carrier 312. Examples of suitable carriers include transparent or translucent glass or plastic materials. The attachment may be accomplished using any of a variety of techniques known to those of skill in the art, including bonding and other attachment techniques. In another example, the previously formed substantially transparent or translucent solar-cell device 304 may be attached directly to a transparent or translucent carrier 312 without the use of an intermediate substrate 308. A protective cover 306 may then also be attached over the solar cell 304, as indicated at block 212. To provide a completed structure that is translucent, the protective cover 306 should also be transparent or translucent. Because the structure will be deployed on buildings where it may be affected by weather and other environmental factors, the protective cover is useful in protecting the surface of the solar cell 304 from damage that those factors might otherwise cause.

The result of these processes 204-212 produces the structure shown in FIG. 3B, in which all of the components are translucent or transparent, providing a structure that is itself translucent or transparent. The structure can accordingly be incorporated as part of a window structure in a building, as indicated at block 216 of FIG. 2. When so deployed, visible light will penetrate through the structure to provide the desired natural illumination within the building, while at the same time exposing the solar cell 304 to light that permits it to convert incident light to energy in the form of a potential difference AV, as indicated at block 220. Energy collected by this conversion process at block 224 may subsequently be used directly in powering devices in the building, stored chemically in a battery or in another form in some other energy-storage device, or otherwise used in producing electrical power.

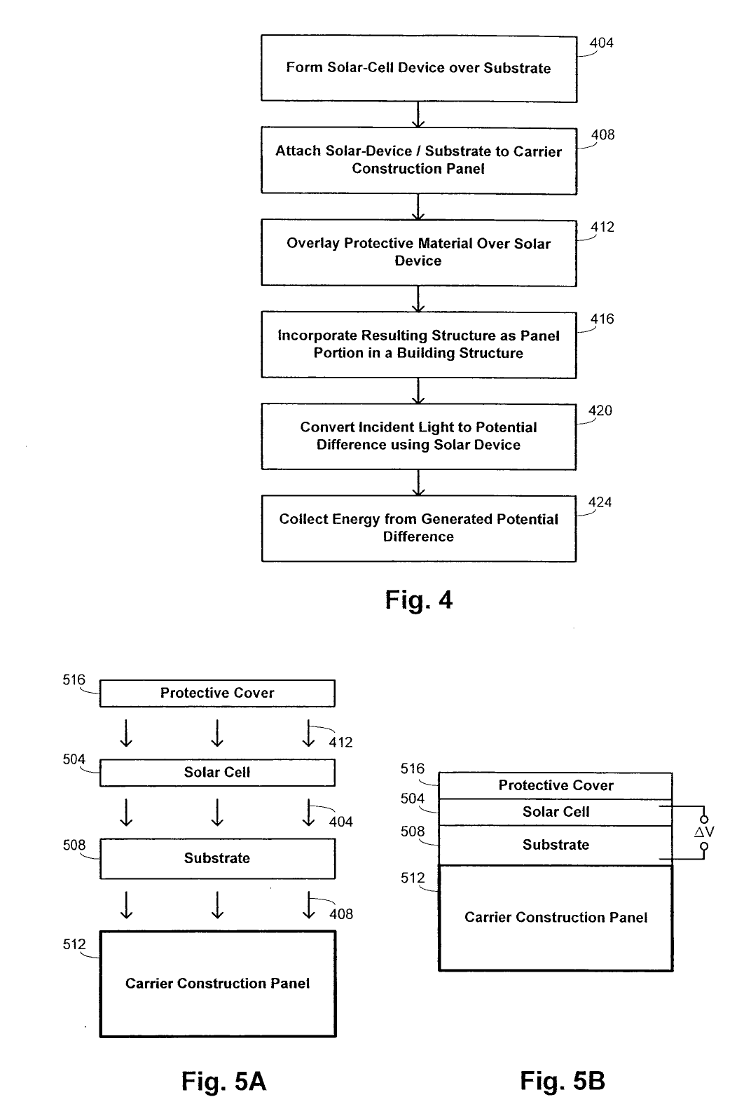

A similar process may be used in fabricating solar cell systems suitable for deployment on opaque portions of the building. This is illustrated with the flow diagram of FIG. 4 and by the schematic drawings in FIGS. 5A and 5B, which have a generally similar structure to FIG. 2 and to FIGS. 3A and 3B respectively. In some respects, fabrication of the solar cell system for deployment on opaque portions of the building provides more flexibility in the selection of materials and fabrication techniques by removing the constraint of having all the components be transparent or translucent. While some embodiments still include transparent or translucent components, other components are opaque at visible wavelengths, causing the resulting structure as a whole to be opaque.

At block 404, a solar-cell device 504 is formed over a substrate 508. Such formation may again proceed using epitaxial growth or some other type of bonding or attachment process in different embodiments. While the substrate could still comprise GaP, other embodiments use materials that are not translucent, such as elemental Si or compound semiconductors like GaAs, InP, and the like. The decision of which substrate to use may thus take greater account of factors other than the optical properties of the substrate than is the case in fabricating solar cell systems for deployment on transparent portions of a building.

The combined solar-device/substrate is attached to a carrier construction panel 512 at block 408. As previously noted, such a construction panel 512 might comprise drivet, light-weight stone, brick, and the like. Because the construction panel 512 need not be translucent, the selection of construction-panel material may be guided by considerations more directly related to the building-fabrication process. For example, materials that are more or less suitable for use in fabricating the structure of the building may be selected in accordance with those criteria without significantly impacting the functionality of the solar cell system.

Similar to fabrication of the solar cell system for transparent regions, a protective cover 516 may be overlaid over the solar cell at block 412. This protective cover 516 is one component that should be transparent or translucent so that light incident on the deployed solar cell system will reach the solar cell 504. The resulting structure may be used to cover panel rows between floors of an office building or to cover other opaque portions of a building at block 416.

The completed structure is shown in FIG. 5B, which identifies a potential difference AV that may be generated at block 420 by converting light incident on the device. Energy may accordingly be collected from this potential difference at block 424 and used to provide power to devices or stored for later use in a manner similar to that described for the translucent structures

Thus, having described several embodiments, it will be recognized by those of skill in the art that various modifications, alternative constructions, and equivalents may be used without departing from the spirit of the invention. Accordingly, the above description should not be taken as limiting the scope of the invention, which is defined in the following claims.

What is claimed is:

1. A method of fabricating a solar cell system, the method comprising:
forming a solar cell over a substrate;
attaching the substrate to a carrier;
overlaying a translucent or transparent protective cover over the solar cell to produce a solar cell system; and
deploying the solar cell system onto an exterior of a building, whereby energy may be generated by conversion of light incident onto the exterior with the solar cell.

2. The method recited in claim 1 wherein forming the solar cell over the substrate comprises growing portions of the solar cell epitaxially over the substrate.

3. The method recited in claim 1 wherein forming the solar cell over the substrate comprises bonding the solar cell to the substrate.

4. The method recited in claim 1 wherein the substrate is translucent at visible wavelengths.

5. The method recited in claim 4 wherein the substrate comprises GaP.

6. The method recited in claim 4 wherein the carrier is translucent or transparent.

7. The method recited in claim 6 wherein the carrier comprises plastic or glass.

8. The method recited in claim 6 wherein deploying the solar cell system onto the exterior of the building comprises deploying the solar cell system as part of a window in the building.

9. The method recited in claim 1 wherein the substrate is opaque at visible wavelengths.

10. The method recited in claim 9 wherein the substrate comprises elemental silicon.

11. The method recited in claim 9 wherein the substrate comprises a compound semiconductor.

12. The method recited in claim 9 wherein the carrier comprises a construction panel.

13. The method recited in claim 12 wherein deploying the solar cell system onto the exterior of the building comprises deploying the solar cell system as part of an opaque portion of the exterior of the building.

14. A method of fabricating a solar cell system, the method comprising:
epitaxially growing a solar cell over a GaP substrate;
attaching the GaP substrate to a translucent or transparent carrier, the carrier comprising plastic or glass;
overlaying a translucent or transparent protective cover over the solar cell to produce a solar cell system; and
deploying the solar cell system as part of a window in a building.

15. A building comprising:
an opaque exterior portion; and
a window, wherein the window comprises:
a translucent or transparent carrier;
a translucent or transparent substrate attached to the carrier;
a solar cell formed over the substrate; and
a translucent or transparent protective cover disposed over the solar cell.

16. The building recited in claim 15 wherein the substrate comprises GaP.

17. The building recited in claim 15 wherein the opaque exterior portion comprises:
a second carrier;
a second substrate attached to the second carrier;
a second solar cell formed over the second substrate; and
a second translucent or transparent protective cover disposed over the second solar cell.

18. The building recited in claim 17 wherein the second substrate is opaque at visible wavelengths.

19. The building recited in claim 17 wherein the carrier comprises a construction panel.

20. A building comprising:
an opaque exterior portion, the opaque exterior portion comprising:
a carrier;
a substrate attached to the carrier;
a solar cell formed over the substrate; and
a translucent or transparent protective cover disposed over the solar cell; and
a window.

21. The building recited in claim 20 wherein the substrate is opaque at visible wavelengths.

22. The building recited in claim 20 wherein the carrier comprises a construction panel.

23. The building recited in claim 20 wherein the window comprises:
a second carrier, wherein the second carrier is translucent or transparent;
a second substrate attached to the second carrier, wherein the second substrate is translucent or transparent;
a second solar cell formed over the second substrate; and
a second translucent or transparent protective cover disposed over the second solar cell.

24. The building recited in claim 23 wherein the second substrate comprises GaP.
